(19) United States
(12) Patent Application Publication
(10) Pub. No.: US 2026/0161538 A1
(43) Pub. Date: Jun. 11, 2026

(54) REGISTER TRANSFER LEVEL (RTL) SIGNALS WAVEFORM REPRESENTATION AND ANALYSIS

(71) Applicant: Singularity Dynamics Private Limited, Bangalore (IN)

(72) Inventor: Harish Kumar, Bangalore (IN)

(21) Appl. No.: 19/416,123

(22) Filed: Dec. 11, 2025

Related U.S. Application Data
(60) Provisional application No. 63/730,477, filed on Dec. 11, 2024.

(51) Int. Cl. G06F 11/3698; G06F 11/362; G06F 30/327

(52) U.S. Cl. CPC G06F 11/3698; G06F 11/3656; G06F 30/327

(57) ABSTRACT

Disclosed subject matter relates to verification and debugging tool and method for selecting signals form RTL code blocks and appending signals to a waveform window. Verification and debugging tool receives RTL code in Hardware Description Language (HDL). Further, verification and debugging tool parses RTL code, and generate abstract syntax tree representing syntactic structure of RTL code. Thereafter, converts abstract syntax tree into RTL directed graph. Furthermore, store, as a template, one or more code blocks, corresponding code block identifiers (CB IDs), locations of one or more code blocks on a visual canvas, and flylines between one or more code blocks. Thereafter, generate one or more waveform windows on visual canvas that display waveforms of one or more signals defined in one or more code blocks over a predefined time period. Finally, display RTL directed graph and one or more waveform windows in spatially distinct locations.

### CROSS-REFERENCE TO RELATED APPLICATIONS

The present application claims the benefit of priority to U.S. Provisional Application No. 63/730,477, filed on Dec. 11, 2024; the contents of which are hereby incorporated by reference herein in their entirety.

### TECHNICAL FIELD

The present disclosure relates to electronic design. Particularly, the present disclosure relates to selecting signals form RTL code blocks and appending the signals to a waveform window.

### BACKGROUND

Modern electronic design is typically performed with Computer-Aided Design (CAD) tools or Electronic Design Automation (EDA) systems. To design an Integrated Circuit (IC) device, a designer first creates high-level behavior descriptions of the IC device using a hardware description language (HDL) such as Verilog and VHDL. As the complexity of the IC devices is growing exponentially due to changes such as shrinking in size of the IC chips and integration of more functionality onto a single IC chip, the behavioral descriptions of the devices are also becoming complex due to a large number of code blocks written in HDL for the IC chips.

A verification engineer usually identifies and resolves the errors or bugs present in the written code blocks using verification and debugging tools. The verification engineer needs to perform multiple iterations in the process of identifying and resolving errors in a code block of the RTL code written in text format. The verification engineer can analyze the value of different signals from the waveform of the signals represented in a waveform window. The existing verification and debugging tools are limited to comprise only one waveform window in which the waveforms of all the signals are represented in a very compact manner. The compact size of the waveform window makes it difficult for the verification engineer to analyze the values of the signals. Further, the waveform window represents waveform of all signals even if the verification engineer needs to analyze only few signal waveforms. Furthermore, the waveform window represents the values of the signals for entire duration even if the verification engineer needs to analyze the waveform over a specified time period.

Therefore, there is a need for a verification and debugging tool that is capable of overcoming the above stated problems.

The information disclosed in this background of the disclosure section is only for enhancement of understanding of the general background of the invention and should not be taken as an acknowledgement or any form of suggestion that this information forms the prior art already known to a person skilled in the art.

### SUMMARY

Disclosed herein is a verification and debugging tool for Register Transfer Level (RTL) code. The verification and debugging tool comprising an input interface configured to receive RTL code in a Hardware Description Language (HDL). Further, the verification and debugging tool comprises an RTL parser configured to parse the RTL code. Thereafter, the verification and debugging tool comprises a graph converter adapted to convert the parsed RTL code into an RTL directed graph. The RTL directed graph directed graph comprises a plurality of code blocks connected by flylines indicating data flow and control flow. Furthermore, the verification and debugging tool comprises a template converter configured to store, as a template, one or more code blocks, corresponding code block identifiers (CB IDs), locations of the one or more code blocks on a visual canvas, and the flylines between the one or more code blocks. Thereafter, the verification and debugging tool comprises a waveform generator configured to generate one or more waveform windows on the visual canvas that display waveforms of one or more signals defined in the one or more code blocks over a predefined time period. Finally, the verification and debugging tool comprises a visual display configured to display the RTL directed graph and the one or more waveform windows in spatially distinct locations, thereby enabling simultaneous visualization of the one or more code blocks and corresponding interconnections.

Further, disclosed herein is a method of selecting signals form RTL code blocks and appending the signals to a waveform window. The method includes receiving RTL code in a Hardware Description Language (HDL). Further, the method includes parsing the RTL code, and generating an abstract syntax tree representing the syntactic structure of the RTL code. Thereafter, the method includes converting the abstract syntax tree into an RTL directed graph. The RTL directed graph comprises a plurality of RTL code blocks represented as nodes and each node corresponding to a functional block of the RTL code. Furthermore, the method includes storing, as a template, one or more code blocks, corresponding code block identifiers (CB IDs), locations of the one or more code blocks on a visual canvas, and the flylines between the one or more code blocks. Thereafter, the method includes generating one or more waveform windows on the visual canvas that display waveforms of one or more signals defined in the one or more code blocks over a predefined time period. Finally, the method includes displaying the RTL directed graph and the one or more waveform windows in spatially distinct locations, thereby enabling simultaneous visualization of the one or more code blocks and corresponding interconnections.

Furthermore, the present disclosure relates to a non-transitory computer readable medium including instructions stored thereon that when processed by at least one processor, cause a verification and debugging tool to perform operations comprising receiving RTL code in a Hardware Description Language (HDL). Further, the instructions cause the processor to parse the RTL code, and generate an abstract syntax tree representing the syntactic structure of the RTL code. Thereafter, the instructions cause the processor to convert the abstract syntax tree into an RTL directed graph. The RTL directed graph comprises a plurality of code blocks connected by flylines indicating data flow and control flow. Furthermore, the instructions cause the processor to store, as a template, one or more code blocks, corresponding code block identifiers (CB IDs), locations of the one or more code blocks on a visual canvas, and the flylines between the one or more code blocks. Thereafter, the instructions cause the processor to generate one or more waveform windows on the visual canvas that display waveforms of one or more signals defined in the one or more code blocks over a predefined time period. Finally, the instructions cause the processor to display the RTL directed graph and the one or more waveform windows in spatially distinct locations, thereby enabling simultaneous visualization of the one or more code blocks and corresponding interconnections.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE ACCOMPANYING DRAWINGS

The accompanying drawings, which are incorporated in and constitute a part of this disclosure, illustrate exemplary embodiments and, together with the description, explain the disclosed principles. In the figures, the left-most digit(s) of a reference number identifies the figure in which the reference number first appears. The same numbers are used throughout the figures to reference like features and components. Some embodiments of system and/or methods in accordance with embodiments of the present subject matter are now described, by way of example only, and regarding the accompanying figures, in which:

FIG. 1 shows an exemplary environment of selecting signals form RTL code blocks and appending the signals to a waveform window, in accordance with some embodiments of the present disclosure;

FIG. 2A illustrates a waveform window on visual canvas, in accordance with some embodiments of the present disclosure;

FIG. 2B illustrates a plurality of waveform window on the visual canvas, in accordance with some embodiments of the present disclosure;

FIG. 3 shows a flowchart illustrating method of selecting signals form RTL code blocks and appending the signals to a waveform window, in accordance with some embodiments of the present disclosure; and

FIG. 4 illustrates a block diagram of an exemplary computer system for implementing embodiments consistent with the present disclosure.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and executed by a computer or processor, whether such computer or processor is explicitly shown.

### DETAILED DESCRIPTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood that it is not intended to limit the disclosure to the specific forms disclosed, but on the contrary, the disclosure is to cover all modifications, equivalents, and alternative falling within the scope of the disclosure.

The terms “comprises”, “comprising”, “includes”, or any other variations thereof, are intended to cover a non-exclusive inclusion, such that a setup, device, or method that comprises a list of components or steps does not include only those components or steps but may include other components or steps not expressly listed or inherent to such setup or device or method. In other words, one or more elements in a system or identity server proceeded by “comprises . . . a” does not, without more constraints, preclude the existence of other elements or additional elements in the system or method.

The terms like “at least one” and “one or more” may be used interchangeably throughout the description.

The terms like “verification and debugging tool”, “verification tool”, “debugging tool” and “tool” may be used interchangeably throughout the description.

The terms like “RTL code” and “code” may be used interchangeably throughout the description.

The terms like “circuit designer” and “designer” may be used interchangeably throughout the description.

The present disclosure relates to a verification and debugging tool that represents the signals of the Register Transfer Level (RTL) code in one or more waveform windows. The RTL code is a coding style used in digital system design and computer engineering, that is written using Hardware Description Language (HDL) like Verilog or VHDL. The RTL code defines the functioning of a digital circuit that may include multiple code blocks. In particular, RTL describes how the data transforms and flows from one register to another. The transformation of data is performed by combinational logic that exists between the registers. The operation of the RTL code is verified by using the verification tool and if any errors or problems arise in the code during its operation, the designer and/or verification engineer may use debugging tool to resolve the problems. The tool disclosed in the present disclosure provides a provision to represent the signals of the RTL code in one or more waveform windows.

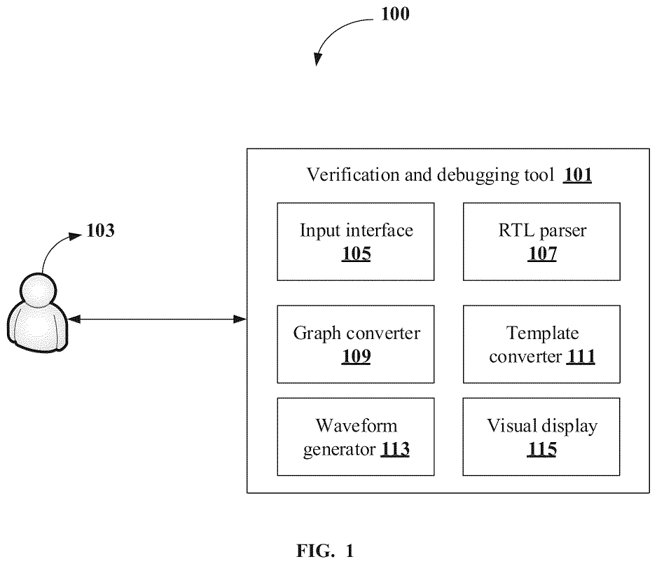

FIG. 1 shows an exemplary environment of selecting signals form RTL code blocks and appending the signals to a waveform window, in accordance with some embodiments of the present disclosure.

Exemplary environment 100 includes a verification and debugging tool 101 and a user 103. The verification and debugging tool 101 may include an input interface 105, an RTL parser 107, a graph converter 109, an template converter 111, a waveform generator 113 and a visual display 115. The user 103 may interact with the verification and debugging tool 101 using the input interface 105 and the visual display 115. The input interface 105 may include, without limitation, keyboards, mouse, touchscreens, and the like, which allow direct user interaction. The input interface 105 may also receive input from any sources provided by the user 103. As an example, the input interface 105 may receive input from Uniform Resource Locator (URL). The output may be displayed on the visual display 115. As an example, the visual display 115 may include, without limitation, an electronic screen, a touchscreen and the like, which allows display of the output. In an embodiment, the verification and debugging tool 101 may be a computing device. As an example, the computing device may be any device used by the user 103 such as, but not limited to, mobile phones, smartphones, laptops, and Personal Computers (PCs). In some embodiments, the verification and debugging tool 101 may be configured within the computing device (not shown in figure).

In an embodiment, the input interface 105 may be configured to receive RTL code in a Hardware Description Language (HDL) from the user 103. The HDLs may include, without limitation, at least one of Verilog and VHSIC Hardware Description Language (VHDL). As an example, the user 103 may be a circuit designer. The RTL code may describe behavior and component connections of a circuit such as an Integrated Circuit (IC). The RTL code may include one or more code blocks describing the operations of one or more entities/components of the circuit. In an embodiment, the input interface 105 may be further configured to validate syntax of the RTL code. If syntax error is detected, the syntax error may be displayed on the visual display 115 allowing the user 103 to edit the RTL code to rectify the syntax error. The input interface 105 may also detect any error which may affect execution of the RTL code.

In an embodiment, upon receiving the RTL code, the RTL parser 107 may be configured to parse the RTL code. In an embodiment, the RTL parser 107 may parse the RTL code by performing lexical and syntactic analysis to identify structural elements such as modules, signals, assignments, and control statements. Based on this analysis, the RTL parser 107 may generate an Abstract Syntax Tree (AST) that represents the hierarchical syntactic structure of the RTL code. The AST may include nodes corresponding to language constructs and captures parent-child relationships between statements, thereby providing a structured and unambiguous representation of the RTL code for subsequent transformation into an RTL directed graph.

In an embodiment, upon generating the AST, the graph converter 109 may be configured to convert the AST into the RTL directed graph. The RTL directed graph may include a plurality of code blocks connected by flylines indicating data flow and control flow. The graph converter 109 may be further configured to represent signals of the RTL code as vertices of the RTL directed graph. The graph converter 109 may also provide one or more customizable display options for the RTL directed graph. The customizable options may enable the user 103 to modify the visual representation of the RTL directed graph to suit specific debugging or analysis requirements. The one or more customizable display options may include, without limitation, color coding for different signal types or logic states, adjustable node sizes to emphasize critical modules, selectable layers for viewing control flow or data flow independently, and variable line thickness or styles to indicate signal width or type. Additional customization may include zoom functionality for detailed inspection of individual nodes, dynamic visual effects to represent changes in signal values over time, and grouping of related nodes into functional sections. These customizable display options enhance clarity, improve navigation within complex RTL designs, and facilitate efficient identification of design issues during verification and debugging. In some embodiments, the RTL directed graph may be configured to display at least one of control flow and data flow. At least one of the control flow and the data flow may be displayed in a visually distinguishable manner. The visual distinction between the control flow and the data flow may be obtained using one of different arrow styles or different colors. In other words, the visual distinction between control flow and data flow within the RTL directed graph is achieved through the use of differentiated graphical indicators. In one embodiment, the distinction is provided by employing different arrow styles, such as solid arrows for data flow and dashed arrows for control flow, or by varying arrowhead shapes to represent signal types. Alternatively, the distinction may be implemented using different colors for the respective flows, enabling clear and intuitive identification of control signals versus data paths. These visual differentiation techniques enhance the readability of complex RTL designs and facilitate efficient debugging and verification by allowing users to quickly interpret the nature of each connection within the graph.

In an embodiment, upon converting the AST into the RTL directed graph, the template converter 111 may be configured to store, as a template, one or more code blocks, corresponding code block identifiers (CB IDs), locations of the one or more code blocks on a visual canvas, and the flylines between the one or more code blocks. Each of the one or more code blocks in the RTL directed graph is assigned a unique identifier as the CB ID. The template converter 111 may be configured to store the locations of the one or more code blocks on the visual canvas in association with their CB IDs.

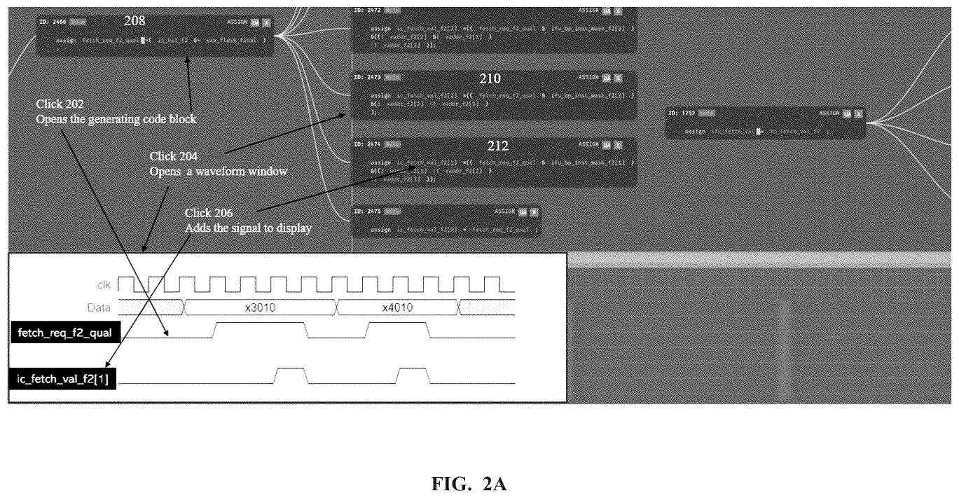

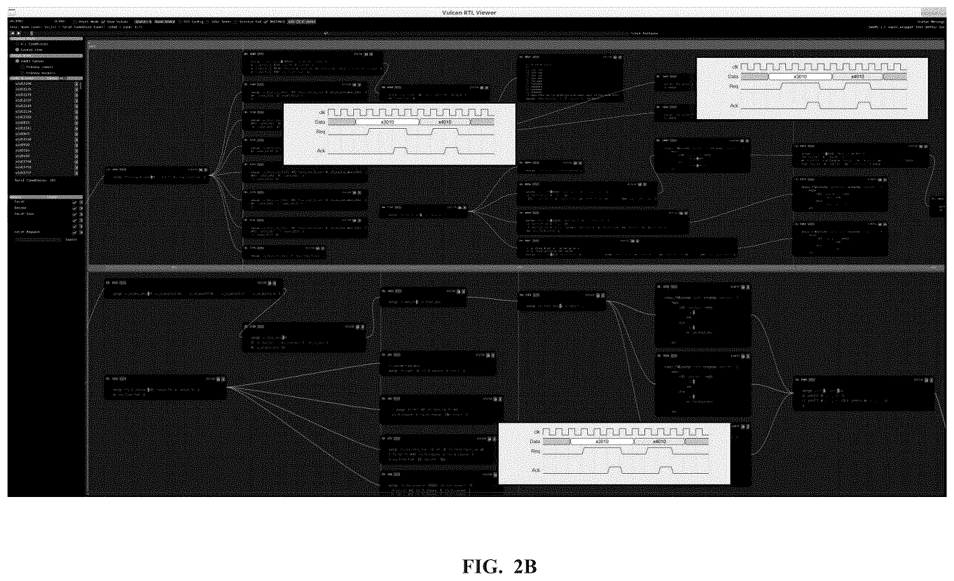

In an embodiment, upon storing the template, the waveform generator 113 may be configured to generate one or more waveform windows on the visual canvas that display waveforms of one or more signals defined in the one or more code blocks over a predefined time period. The waveforms displayed in a waveform window are selectable by point-and-click, enabling the user 103 to add one or more signals from a code block to a selected waveform window. The waveform generator 113 may be configured to generate a separate waveform window for a selected code block, the separate waveform window including waveforms of signals defined in the selected code block. The waveforms generated by the waveform generator 113 may provide a forward reference by enabling selection of a code block to populate a waveform window with waveforms of signals defined in that code block, and a backward reference by enabling selection of a waveform of a signal to display the code block from which the signal is generated. Exemplary illustrations are provided in FIGS. 2A and 2B.

In an embodiment, upon generating the waveforms, the visual display 115 may be configured to display the RTL directed graph and the one or more waveform windows in spatially distinct locations, thereby enabling simultaneous visualization of the one or more code blocks and corresponding interconnections. The visual display 115 may display a plurality of waveform windows that are spatially located at different areas on the visual canvas. In an embodiment, when user 103 hovers over a code block, the visual display 115 may temporarily display signals and corresponding waveforms for currently hovered code block, and hovering over a signal temporarily displays the corresponding waveform. The waveform of a selected signal may be displayed for a time period specified by the user 103. Additional sensitive regions in and around waveform windows are bound to user-accessible functionalities. The waveform windows may further display clock signals and data values. The visual display 115 and the output interface may also display results in a graphical format. In an embodiment, the visual display 115 may be configured to support zoom functionality for viewing details of individual code blocks or nodes. The zoom functionality may allow the user 103 to focus on specific areas of the RTL directed graph while preserving the ability to return to an overall view. The visual display 115 may also include user interface which may allow the user interactions within the visual display 115. The user interface may allow the user 103 to group multiple code blocks into functional sections. The visual display 115 provides an integrated environment for real-time analysis and debugging of RTL designs. By generating the waveforms dynamically, the verification and debugging tool 101 enhances interpretability of RTL graphs and reduces ambiguity during debugging. This capability enables engineers to track signal name changes across hierarchical levels. As a result, verification workflows become more efficient, accelerating error localization and minimizing the time required to identify and resolve functional issues.

FIG. 2A illustrates a waveform window on the visual canvas, in accordance with an exemplary embodiment of the present disclosure. The stated representation is an exemplary embodiment and should not be construed as a limitation.

The graph converter 109 may display the one or more code blocks as the RTL DG on the visual canvas. The one or more signals in a code block may be connected to other signals in other code blocks through the one or more flylines as depicted in FIG. 2A. Present disclosure provides a unique way to switch from the signals of the waveform window to the Code block and vice-versa. Same can be understood in below paragraphs.

The designer may click (202) on a waveform of a signal “fetch_req_f2_equal” present in the waveform window that may direct the designer or verification engineer to display code block 208 from where the signal “fetch_req_f2_equal” is generated. It may be understood that the waveform generator 113 may use a point and click mechanism to display the code block 208.

The designer may click (204) on a code block 210 among the one or more code blocks in the RTL DG. The RTL DG comprises a plurality of code blocks connected by flylines indicating data flow and control flow. By clicking on the code block 210, the waveform generator 118 may generate a separate waveform window for the code block 210. The waveform window may include one or more waveforms of one or more signals defined in the code block 210. In an exemplary embodiment, the signal “fetch_req_f2_equal” may be defined as fan-in in the code block 210. Thus, the signal “fetch_req_f2_equal” in the code block 208 may be connected to the signal “fetch_req_f2_equal” in the code block 210 through flyline. Once, the click 204 is hit for code block 210, the waveform window may include the waveform of the signal “fetch_req_f2_equal”. It may be appreciated that the waveform generator 118 may display the waveform of the signal “fetch_req_f2_equal” for a time period specified by the designer.

The designer may click (206) on a signal “ic_fetch_val_f2[1]” defined in code block 212. The waveform generator 118 may use the point and click mechanism to add the waveform of the signal “ic_fetch_val_f2[1]” to a waveform window. In an exemplary embodiment, the designer may first click on the boundary of a waveform window already displayed on the visual canvas and may subsequently select the one or more signals using the point and click mechanism. In this manner, the waveform generator 113 may display the waveforms of the selected signals in the waveform window of which the boundary was selected. The designer may click on the boundary of different waveform windows to display the waveforms of the one or more signals in different waveform windows. In another embodiment, the waveform generator 113 may generate a new waveform window to display the waveform of the signal ic_fetch_val_f2[1]. Hence, a forward reference for adding one or more signals to the one or more waveform windows and a backward reference for of showing the generating code block for a signal on the waveform window may be made.

FIG. 2B illustrates a plurality of waveform windows on the visual canvas, in accordance with an embodiment of the present disclosure. The plurality of waveform windows may be spatially located at different areas on the visual canvas. The plurality of waveform windows may correspond to the one or more code blocks of the RTL code. In an embodiment, the plurality of waveform windows may correspond to the one or more signals defined in the one or more code blocks.

In an embodiment, the designer may hover over a code block to generate a temporary view of signals and their corresponding waveforms on the waveform window for the corresponding code block. Similarly, the designer may hover over a signal to generate a temporary view for the corresponding signal in the waveform window. In an embodiment, the waveform window may also display clock signals and data values, but not limited thereto. Further, additional sensitive regions in and around waveform windows may bound to certain functionalities.

The waveform windows offer a powerful means to visualize and optimize the RTL code objects that may enhance the design process, making it more efficient and manageable for the verification and/or design engineers.

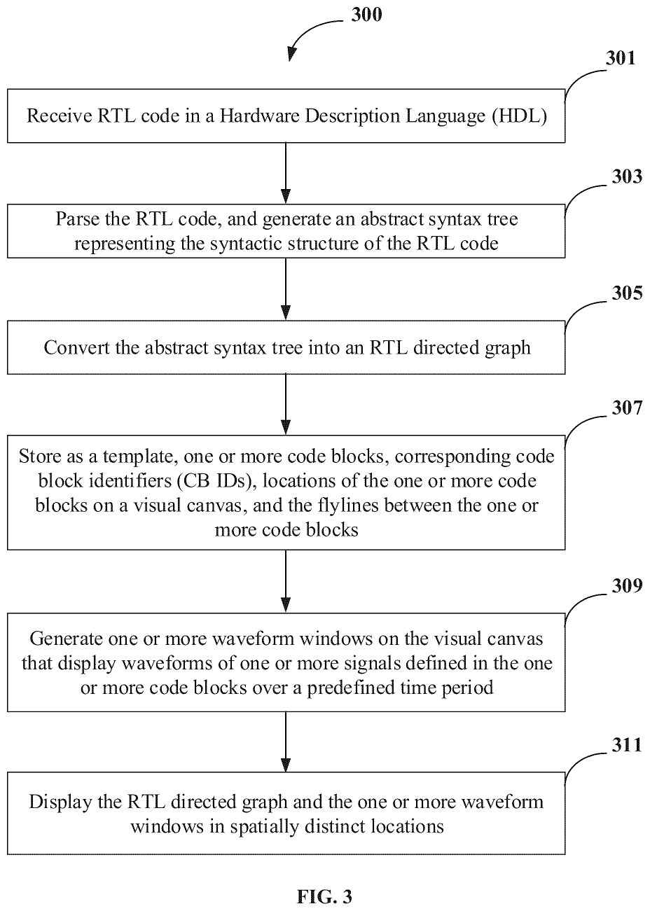

FIG. 3 is a flowchart illustrating a method of selecting signals form RTL code blocks and appending the signals to a waveform window, in accordance with some embodiments of the present disclosure.

As illustrated in FIG. 3, the method 300 may include one or more blocks illustrating a method of selecting signals form RTL code blocks and appending the signals to a waveform window, using the verification and debugging tool 101 illustrated in FIG. 1. The method 300 may be described in the general context of computer executable instructions. Generally, computer executable instructions can include routines, programs, objects, components, data structures, procedures, modules, and functions, which perform specific functions or implement specific abstract data types.

The order in which the method 300 is described is not intended to be construed as a limitation, and any number of the described method blocks can be combined in any order to implement the method. Additionally, individual blocks may be deleted from the methods without departing from the scope of the subject matter described herein. Furthermore, the method can be implemented in any suitable hardware, software, firmware, or combination thereof.

At block 301, the method 300 includes receiving, by a processor of the verification and debugging tool 101, RTL code in a Hardware Description Language (HDL). The HDLs may include at least one of Verilog and VHSIC Hardware Description Language (VHDL). Further, the processor may validate syntax of the RTL code.

At block 303, the method 300 includes parsing, by the processor, the RTL code, and generating an abstract syntax tree representing the syntactic structure of the RTL code.

At block 305, the method 300 includes converting, by the processor, the abstract syntax tree into an RTL directed graph. The RTL directed graph comprises a plurality of code blocks connected by flylines indicating data flow and control flow. The processor may represent signals as vertices and flylines to indicate fan-in and fan-out connections between RTL code blocks. Further, the processor may provide one or more customizable display options for the RTL directed graph. The processor may support zoom functionality for viewing details of individual code blocks or nodes. The zoom functionality may allow a user 103 to focus on specific areas of the RTL directed graph while preserving ability to return to an overall view. The RTL directed graph may be configured to display least one of control flow and data flow, wherein the at least one of the control flow and the data flow is displayed in a visually distinguishable manner.

At block 307, the method 300 includes storing, by the processor, store, as a template, one or more code blocks, corresponding code block identifiers (CB IDs), locations of the one or more code blocks on a visual canvas, and the flylines between the one or more code blocks. Each of the one or more code blocks in the RTL directed graph is assigned a unique identifier as the CB ID. The processor may configure the template converter 111 to store the locations of the one or more code blocks on the visual canvas in association with their CB IDs.

At block 309, the method 300 includes generating, by the processor, one or more waveform windows on the visual canvas that display waveforms of one or more signals defined in the one or more code blocks over a predefined time period. The waveforms displayed in a waveform window are selectable by point-and-click, enable the user 103 to add one or more signals from a code block to a selected waveform window. The processor may configure the waveform generator 113 to generate a separate waveform window for a selected code block, the separate waveform window including waveforms of signals defined in the selected code block. The processor may configure the waveform generator 113 to provide a forward reference by enabling selection of a code block to populate a waveform window with waveforms of signals defined in that code block, and a backward reference by enabling selection of a waveform of a signal to display the code block from which the signal is generated.

At block 311, the method 300 includes displaying, by the processor, the RTL directed graph and the one or more waveform windows in spatially distinct locations, thereby enabling simultaneous visualization of the one or more code blocks and corresponding interconnections. The processor may configure the visual display 115 to display a plurality of waveform windows that are spatially located at different areas on the visual canvas. In an embodiment, when user 103 hovers over a code block, the processor may configure the visual display 115 to temporarily displays signals and corresponding waveforms for currently hovered code block, and hovering over a signal temporarily displays the corresponding waveform. The waveform of a selected signal may be displayed for a time period specified by the user 103. Additional sensitive regions in and around waveform windows are bound to user-accessible functionalities. The waveform windows may further display clock signals and data values. The processor may configure the processor may configure the visual display 115 to support zoom functionality for viewing details of individual code blocks or nodes. The zoom functionality may allow the user 103 to focus on specific areas of the RTL directed graph while preserving the ability to return to an overall view.

### Computer System

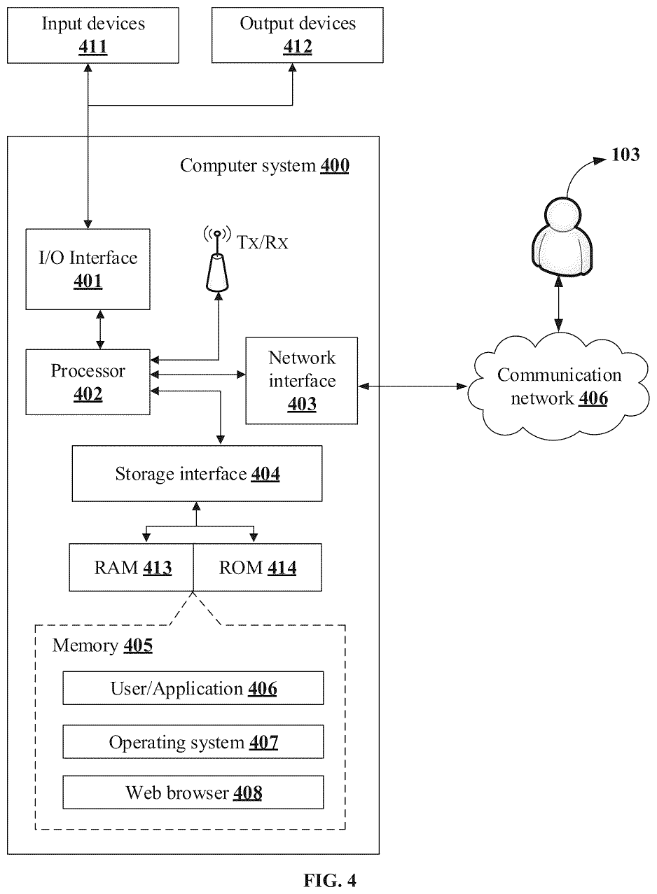

FIG. 4 illustrates a block diagram of an exemplary computer system 400 for implementing embodiments consistent with the present disclosure. In an embodiment, the computer system 400 may be a verification and debugging tool 101 illustrated in FIG. 1. The computer system 400 may include a central processing unit (“CPU” or “processor” or “memory controller”) 402. The processor 402 may comprise at least one data processor for executing program components for executing user- or system-generated business processes. A user may include a network manager, an application developer, a programmer, an organization, or any system/sub-system being operated parallelly to the computer system 400. The processor 402 may include specialized processing units such as integrated system (bus) controllers, memory controllers/memory management control units, floating point units, graphics processing units, digital signal processing units, etc.

The processor 402 may be disposed in communication with one or more Input/Output (I/O) devices (411 and 412) via I/O interface 401. The I/O interface 401 may employ communication protocols/methods such as, without limitation, audio, analog, digital, stereo, IEEER-1394, serial bus, Universal Serial Bus (USB), infrared, PS/2, BNC, coaxial, component, composite, Digital Visual Interface (DVI), high-definition multimedia interface (HDMI), Radio Frequency (RF) antennas, S-Video, Video Graphics Array (VGA), IEEE 802.n/b/g/n/x, Bluetooth, cellular (e.g., Code-Division Multiple Access (CDMA), High-Speed Packet Access (HSPA+), Global System For Mobile Communications (GSM), Long-Term Evolution (LTE) or the like), etc. Using the I/O interface 401, the computer system 400 may communicate with one or more I/O devices 411 and 412.

In some embodiments, the processor 402 may be disposed in communication with a network 409 via a network interface 403. The network interface 403 may communicate with the network 409. The network interface 403 may employ connection protocols including, without limitation, direct connect, Ethernet (e.g., twisted pair 10/100/1000 Base T), Transmission Control Protocol/Internet Protocol (TCP/IP), token ring, IEEE 802.11a/b/g/n/x, etc.

In an implementation, the preferred network 409 may be implemented as one of the several types of networks, such as intranet or Local Area Network (LAN) and such within the organization. The preferred network 409 may either be a dedicated network or a shared network, which represents an association of several types of networks that use a variety of protocols, for example, Hypertext Transfer Protocol (HTTP), Transmission Control Protocol/Internet Protocol (TCP/IP), Wireless Application Protocol (WAP) etc., to communicate with each other. Further, the network 409 may include a variety of network devices, including routers, bridges, RAN nodes, computing devices, storage devices, etc. Using the network interface 403 and the network 409, the computer system 400 may communicate with a user 103.

In some embodiments, the processor 402 may be disposed in communication with a memory 405 (e.g., RAM 413, ROM 414, etc. as shown in FIG. 6) via a storage interface 404. The storage interface 404 may connect to memory 405 including, without limitation, memory drives, removable disc drives, etc., employing connection protocols such as Serial Advanced Technology Attachment (SATA), Integrated Drive Electronics (IDE), IEEE-1394, Universal Serial Bus (USB), fiber channel, Small Computer Systems Interface (SCSI), etc. The memory drives may further include a drum, magnetic disc drive, magneto-optical drive, optical drive, Redundant Array of Independent Discs (RAID), solid-state memory devices, solid-state drives, etc.

The memory 405 may store a collection of program or database components, including, without limitation, user/application interface 406, an operating system 407, a web browser 408, and the like. In some embodiments, computer system 400 may store user/application data 406, such as the data, variables, records, etc. as described in this invention. Such databases may be implemented as fault-tolerant, relational, scalable, secure databases such as Oracle® or Sybase®.

The operating system 407 may facilitate resource management and operation of the computer system 400. Examples of operating systems include, without limitation, APPLE® MACINTOSH® OS X®, UNIX®, UNIX-like system distributions (E.G., BERKELEY SOFTWARE DISTRIBUTION® (BSD), FREEBSD®, NETBSD®, OPENBSD, etc.), LINUX® DISTRIBUTIONS (E.G., RED HAT®, UBUNTU®, KUBUNTU®, etc.), IBM® OS/2®, MICROSOFT® WINDOWS® (XP®, VISTA®/7/8, 10 etc.), APPLE® IOS®, GOOGLE™ ANDROID™, BLACKBERRY® OS, or the like.

The user interface 406 may facilitate display, execution, interaction, manipulation, or operation of program components through textual or graphical facilities. For example, the user interface 406 may provide computer interaction interface elements on a display system operatively connected to the computer system 400, such as cursors, icons, check boxes, menus, scrollers, windows, widgets, and the like. Further, Graphical User Interfaces (GUIs) may be employed, including, without limitation, APPLE® MACINTOSH® operating systems' Aqua®, IBM® OS/2®, MICROSOFT® WINDOWS® (e.g., Aero, Metro, etc.), web interface libraries (e.g., ActiveX®, JAVA®, JAVASCRIPT®, AJAX, HTML, ADOBE® FLASH®, etc.), or the like.

The web browser 408 may be a hypertext viewing application. Secure web browsing may be provided using Secure Hypertext Transport Protocol (HTTPS), Secure Sockets Layer (SSL), Transport Layer Security (TLS), and the like. The web browsers 408 may utilize facilities such as AJAX, DHTML, ADOBE® FLASH®, JAVASCRIPT®, JAVA®, Application Programming Interfaces (APIs), and the like. Further, the computer system 400 may implement a mail RAN node stored program component. The mail RAN node may utilize facilities such as ASP, ACTIVEX®, ANSI® C++/C #, MICROSOFT®, .NET, CGI SCRIPTS, JAVA®, JAVASCRIPT®, PERL®, PHP, PYTHON®, WEBOBJECTS®, etc. The mail RAN node may utilize communication protocols such as Internet Message Access Protocol (IMAP), Messaging Application Programming Interface (MAPI), MICROSOFT exchange, Post Office Protocol (POP), Simple Mail Transfer Protocol (SMTP), or the like. In some embodiments, the computer system 400 may implement a mail client stored program component. The mail client may be a mail viewing application, such as APPLE® MAIL, MICROSOFT® ENTOURAGE®, MICROSOFT® OUTLOOK®, MOZILLA® THUNDERBIRD®, and the like.

Furthermore, one or more computer-readable storage media may be utilized in implementing embodiments consistent with the present invention. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., non-transitory. Examples include Random Access Memory (RAM), Read-Only Memory (ROM), volatile memory, nonvolatile memory, hard drives, Compact Disc (CD) ROMs, Digital Video Disc (DVDs), flash drives, disks, and any other known physical storage media.

In light of the technical advancements provided by the disclosed method, the claimed steps, as discussed above, are not routine, conventional, or not well-known aspects in the art, as the claimed steps provide the aforesaid solutions to the technical problems existing in the conventional technologies. Further, the claimed steps clearly bring an improvement in the functioning of the system itself, as the claimed steps provide a technical solution to a technical problem.

The terms “an embodiment”, “embodiment”, “embodiments”, “the embodiment”, “the embodiments”, “one or more embodiments”, “some embodiments”, and “one embodiment” mean “one or more (but not all) embodiments of the invention(s)” unless expressly specified otherwise.

The terms “including”, “comprising”, “having” and variations thereof mean “including but not limited to”, unless expressly specified otherwise.

The enumerated listing of items does not imply that any or all the items are mutually exclusive, unless expressly specified otherwise. The terms “a”, “an” and “the” mean “one or more”, unless expressly specified otherwise.

A description of an embodiment with several components in communication with each other does not imply that all such components are required. On the contrary, a variety of optional components are described to illustrate the wide variety of possible embodiments of the invention.

When a single device or article is described herein, it will be clear that more than one device/article (whether they cooperate) may be used in place of a single device/article. Similarly, where more than one device/article is described herein (whether they cooperate), it will be clear that a single device/article may be used in place of the more than one device/article or a different number of devices/articles may be used instead of the shown number of devices or programs. The functionality and/or features of a device may be alternatively embodied by one or more other devices which are not explicitly described as having such functionality/features. Thus, other embodiments of invention need not include the device itself.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the embodiments of the present invention are intended to be illustrative, but not limiting, of the scope of the invention, which is set forth in the following claims.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A verification and debugging tool for Register Transfer Level (RTL) code, the verification and debugging tool comprising:
an input interface configured to receive RTL code in a Hardware Description Language (HDL);
an RTL parser configured to parse the RTL code;
a graph converter configured to convert the parsed RTL code into an RTL directed graph, wherein the RTL directed graph comprises a plurality of code blocks connected by flylines indicating data flow and control flow;
a template converter configured to store, as a template, one or more code blocks, corresponding code block identifiers (CB IDs), locations of the one or more code blocks on a visual canvas, and the flylines between the one or more code blocks;
a waveform generator configured to generate one or more waveform windows on the visual canvas that display waveforms of one or more signals defined in the one or more code blocks over a predefined time period; and
a visual display configured to display the RTL directed graph and the one or more waveform windows in spatially distinct locations, thereby enabling simultaneous visualization of the one or more code blocks and corresponding interconnections.

2. The verification and debugging tool of claim 1, wherein each of the one or more code blocks in the RTL directed graph is assigned a unique identifier as the CB ID.

3. The verification and debugging tool of claim 1, wherein the template converter is configured to store the locations of the one or more code blocks on the visual canvas in association with their CB IDs.

4. The verification and debugging tool of claim 1, wherein the waveforms displayed in a waveform window are selectable by point-and-click, enabling a user to add one or more signals from a code block to a selected waveform window.

5. The verification and debugging tool of claim 1, wherein the waveform generator is configured to generate a separate waveform window for a selected code block, the separate waveform window including waveforms of signals defined in the selected code block.

6. The verification and debugging tool of claim 1, wherein the waveform generator provides a forward reference by enabling selection of a code block to populate a waveform window with waveforms of signals defined in that code block, and a backward reference by enabling selection of a waveform of a signal to display the code block from which the signal is generated.

7. The verification and debugging tool of claim 1, wherein the visual display is configured to display a plurality of waveform windows that are spatially located at different areas on the visual canvas.

8. The verification and debugging tool of claim 1, wherein hovering over a code block temporarily displays signals and corresponding waveforms for currently hovered code block, and hovering over a signal temporarily displays the corresponding waveform.

9. The verification and debugging tool of claim 1, wherein the waveform windows further display clock signals and data values.

10. The verification and debugging tool of claim 1, wherein directional flylines among code blocks visually indicate net connections between different code blocks in the RTL directed graph.

11. The verification and debugging tool of claim 1, wherein the waveform generator is configured to display the waveform of a selected signal for a time period specified by a user.

12. The verification and debugging tool of claim 1, wherein additional sensitive regions in and around waveform windows are bound to user-accessible functionalities.

13. The verification and debugging tool of claim 1, wherein the graph converter is further configured to provide one or more customizable display options for the RTL directed graph.

14. The verification and debugging tool of claim 13, wherein the one or more customizable display options comprises at least one of color coding for different types of signals, adjustable node sizes, and selectable layers of data flow representation.

15. The verification and debugging tool of claim 1, wherein the visual display is configured to support zoom functionality for viewing details of individual code blocks or nodes.

16. The verification and debugging tool of claim 15, wherein the zoom functionality allows a user to focus on specific areas of the RTL directed graph while preserving ability to return to an overall view.

17. The verification and debugging tool of claim 1, wherein the RTL directed graph is configured to display at least one of control flow and data flow, wherein the at least one of the control flow and the data flow is displayed in a visually distinguishable manner.

18. The verification and debugging tool of claim 1, wherein the visual display enables a switch between visualization of signals in a waveform window and visualization of the corresponding generating code block.

19. A method of selecting signals form RTL code blocks and appending the signals to a waveform window, the method comprising:
receiving RTL code in a Hardware Description Language (HDL);
parsing the RTL code, and generating an abstract syntax tree representing the syntactic structure of the RTL code;
converting the abstract syntax tree into an RTL directed graph, wherein the RTL directed graph comprises a plurality of code blocks connected by flylines indicating data flow and control flow;
storing, as a template, one or more code blocks, corresponding code block identifiers (CB IDs), locations of the one or more code blocks on a visual canvas, and the flylines between the one or more code blocks;
generating one or more waveform windows on the visual canvas that display waveforms of one or more signals defined in the one or more code blocks over a predefined time period; and
displaying the RTL directed graph and the one or more waveform windows in spatially distinct locations, thereby enabling simultaneous visualization of the one or more code blocks and corresponding interconnections.

20. A non-transitory computer readable medium including instructions stored thereon that when processed by at least one processor, cause a verification and debugging tool to perform operations comprising:
receiving RTL code in a Hardware Description Language (HDL);
parsing the RTL code, and generating an abstract syntax tree representing the syntactic structure of the RTL code;
converting the abstract syntax tree into an RTL directed graph, wherein the RTL directed graph comprises a plurality of code blocks connected by flylines indicating data flow and control flow;
storing, as a template, one or more code blocks, corresponding code block identifiers (CB IDs), locations of the one or more code blocks on a visual canvas, and the flylines between the one or more code blocks;
generating one or more waveform windows on the visual canvas that display waveforms of one or more signals defined in the one or more code blocks over a predefined time period; and
displaying the RTL directed graph and the one or more waveform windows in spatially distinct locations, thereby enabling simultaneous visualization of the one or more code blocks and corresponding interconnections.
